(19) United States
(12) Patent Application Publication
(10) Pub. No.: US 2010/0264471 A1
(43) Pub. Date: Oct. 21, 2010

(54) Enhancing MOSFET performance with stressed wedges

(76) Inventor: Huilong Zhu, Poughkeepsie, NY (US)

Correspondence Address: Huilong Zhu, 93 Autumn Dr., Poughkeepsie, NY, 12603, US

(21) Appl. No.: 12/798,699

(22) Filed: Apr. 10, 2010

Related U.S. Application Data
(60) Provisional application No. 61/212,670, filed on Apr. 15, 2009.

(51) Int. Cl. H01L 29/78; H01L 21/31

(52) U.S. Cl. 257/288; 438/702; 257/E29.255; 257/E21.24

(57) ABSTRACT

The present invention relates to improved metal-oxide-semiconductor field effect transistor (MOSFET) devices with stress-inducing structures located above the gate structure or at or near the source and drain regions. Specifically, a dielectric layer in on the MOSFET and at least one stress-inducing wedge is pressed into the dielectric layer to induce a stress in the channel of the MOSFET. The at least one stress-inducing wedge is located above the gate of an n-channel MOSFET (nMOSFET) and the at least one stress-inducing wedge is located in or near the source and drain regions, but not above the gate of a p-channel MOSFET (pMOSFET). The former creates tensile stress in the channel of an nMOSFET and then enhance the performance of the nMOSFET. The latter produces compressive stress in the channel of a pMOSFET and then enhance the performance of the pMOSFET.

This non-provisional application claims the benefit of the provisional application filed with the United States Patent and Trademark Office as Ser. No. 61/212,670 entitled “ENHANCING MOSFET PERFORMANCE WITH STRESSED WEDGES” filed on Apr. 15, 2009.

### FIELD OF THE INVENTION

The present invention relates generally to semiconductor devices for integrated circuits, and particularly to metal-oxide-semiconductor field-effect transistor (MOSFET) with improved performance through strain engineering.

### BACKGROUND OF THE INVENTION

Using stress is an effective way improving the minority carrier mobility in a metal-oxide-semiconductor field-effect transistor (MOSFET) and providing significant enhancement of the performance of the MOSFET that requires relatively low costs for modifications of manufacturing processes.

Strain in a semiconductor can alter the band gap structure and the effective mass of carriers in the semiconductor. When stresses are applied to channels of MOSFETs, the mobility of carriers, and as a consequence, the transconductance and the on-current of the MOSFET can be improved. When applied in a longitudinal direction (i.e., in the direction of on-current flow), tensile stress is known to enhance electron mobility (or n-channel MOSFET (nMOSFET) drive currents) while compressive stress is known to enhance hole mobility (or p-channel MOSFET (pMOSFET) drive currents). These opposite requirements for the type of stress for enhancing carrier mobility between the nMOSFETs and pMOSFETs have led to prior art methods for applying at least two different types of stresses to the semiconductor devices on the same integrated chip.

Various methods of “strain engineering” or “stress engineering” on the channel of a MOSFET have been known in prior art. The most effective way to enhance MOSFET performance with stresses is so called “local stress” that generates stresses in the channel of a MOSFET through the stressors like stress liners, embedded strained SiGe or Si:C source/drain, stressed gate, stressed shallow trench isolation, and stressed silicides.

For last four decades, the minimum feature size of electronic devices is scaled down dramatically in order to reduce manufacturing costs and enhance IC performance. It makes more and more difficult to apply strong stresses to the channel of a MOSFET if the minimum spacing (i.e., the minimum pitch) between MOSFETs becoming small due to the increasing of adverse boundary effect of stressors and the limitations of small stressor volume. Stresses in the stressors used in prior art are usually intrinsic, which are produced in film deposition or growth. It is difficult to further increase the stress level after the film deposition or growth.

In present invention, the limitations and difficulties mentioned-above can be solved by introducing stressed wedges, which allow to further increase stress level after the wedge formation or to enhance device performance by applying extrinsic stresses. The stressed wedges have ability to memorize the applied extrinsic stresses and then enhance device performance even after removing the applied extrinsic stresses. The present invention provides efficient and low cost structures and methods to improve MOSFET performance with extrinsic strain engineering or stress engineering.

Various strained MOSFETs have been proposed by Doris et al U.S. Patent Application US2005/0093030A1, Yang et al U.S. Pat. No. 7,462,915, Murthy et al U.S. Pat. No. 7,226,842, Packan et al, “High Performance 32 nm Logic Technology Featuring 2^{nd} Generation High-k+Metal Gate Transistors,” IEDM, pp.659-662, 2009 International Electron Devices Meeting (2009), Yang et al., “Dual Stress Liner for High-performance Sub-45 nm Gate-length SOI CMOS Manufacturing,” IEDM, pp. 1075-1078, 2004 International Electron Devices Meeting (2004) and Thompson et al., “A Logic Nanotechnology Featuring Strained-Silicon”, IEEE Electron Device Letters, Vol. 25, No. 4, (2004), pp191-193, the disclosures of which are incorporated by reference herein.

Of the foregoing references, Doris et al U.S. Patent Application US2005/0093030A1 discloses forming different stressed dielectric liner on nMOSFET and pMOSFET, separately. Yang et al U.S. Pat. No. 7,462,915 discloses a method to enhance stress in the channel of a MOSFET by optimizing liner shape and spacer arrangement. Murthy et al U.S. Pat. No. 7,226,842 discloses a structure of embedded strained source/drain to create stress in the channel of a MOSFET. Packan et al paper discussed the benefits of the combination of High-k Metal Gate and stress engineering. Yang et al disclosed a method of using dual stress liner to obtain high-performance of sub-45 nm gate-length SOI CMOS devices. Thompson et al paper discloses the formation of embedded strained source/drain to enhance pMOSFET performance.

A high performance and low power consumption integrated circuit (IC) usually is formed by high performance CMOS devices. The high performance CMOS devices usually require strong stresses in the channels of the CMOS devices. It is difficult to obtain strong stresses when either the minimum feature size of CMOS devices is scaled down or the intrinsic stress level in a stressor reaches its maximum value. There exists a need for a high performance integrated circuit that the scaling of the minimum feature size of CMOS devices and the limitation of the maximum intrinsic stress level in a stressor does not adversely impact the enhancement of integrated circuits and the cost reduction of integrated circuit manufacturing.

### BRIEF SUMMARY OF THE INVENTION

The present invention addresses the needs described above by providing efficient and low cost structures and methods to improve MOSFET performance with extrinsic strain engineering or stress engineering. The present invention discloses methods to form wedges within proximity of MOSFETs. External forces are applied to move the wedges to produce stress in the channel of the MOSFETs, which allows enhancing the performance of the MOSFETs by applying external forces or stresses on an IC in a manufacturing process.

The various advantages and purposes of the present invention as described above and hereafter are achieved by providing, according to a first aspect of the invention, a method of making strained MOSFETs, comprising the steps of:

forming at least one nMOSFET on a semiconductor wafer;

forming a first dielectric layer on the at least one nMOSFET;

forming a second dielectric layer on the top of the first dielectric layer, wherein the second dielectric layer has small viscosity at temperature greater than about 200 C-800 C;

conducting chemical mechanical polishing (CMP) to planarize the second dielectric layer;

forming a hardmask on the top of the second dielectric layer, wherein the hardmask has at least one opening hole above the gate of the at least one nMOSFET;

forming at least one first inverted trapezoidal trench on the top of the gate of the at least one nMOSFET, wherein the at least one inverted trapezoidal trench extends through the second dielectric layer and the first dielectric layer;

refilling the at least one first inverted trapezoidal trench by depositing a third dielectric layer, wherein the third dielectric layer has small viscosity at temperature greater than about 200 C-800 C;

forming at least one second inverted trapezoidal trench with the hardmask above the gate of the at least one nMOSFET, wherein the bottom of the at least one second inverted trapezoidal trench is preferably close or near the top surface of the first dielectric layer and the at least one second inverted trapezoidal trench does not extend through the third dielectric layer;

refilling the at least one second inverted trapezoidal trench by depositing a fourth dielectric layer, wherein,the part of the fourth dielectric layer filled in the at least one second inverted trapezoidal trench forms at least one wedge;

etching part of the fourth dielectric layer and the hardmask to expose part of the second dielectric layer;

applying pressure on the fourth dielectric layer and annealing at temperature about 200 C-800 C to push the at least one wedge toward the at least one nMOSFET, wherein the at least one wedge is pressed by the first dielectric layer or the first dielectric layer is pushed outwards relative to the at least one wedge, which produces a tensile stress in a longitudinal direction (i.e., in the direction of on-current flow) in the channel of the at least one nMOSFET.

According to a second aspect of the invention, there is provided a method of making strained MOSFETs, comprising the steps of:

forming at least one pMOSFET on a semiconductor wafer;

forming a first dielectric layer on the at least one pMOSFET;

forming a second dielectric layer on the top of the first dielectric layer, wherein the second dielectric layer has small viscosity at temperature greater than about 200 C-800 C;

conducting chemical mechanical polishing (CMP) to planarize the second dielectric layer;

forming a hardmask on the top of the second dielectric layer, wherein the hardmask has at least one opening hole above the area in or near source/drain of the at least one pMOSFET, but not above the gate of the at least one pMOSFET;

forming at least one first inverted trapezoidal trench in or near source/drain area of the at least one pMOSFET, but not on the top of the gate of the at least one pMOSFET, wherein the at least one inverted trapezoidal trench extends through the second dielectric layer and the first dielectric layer;

refilling the at least one first inverted trapezoidal trench by depositing a third dielectric layer, wherein the third dielectric layer has small viscosity at temperature greater than about 200 C-800 C;

forming at least one second inverted trapezoidal trench with the hardmask above the area in or near source/drain of the at least one pMOSFET, wherein the bottom of the at least one second inverted trapezoidal trench is preferably close or near the top surface of the first dielectric layer and the at least one second inverted trapezoidal trench does not extend through the third dielectric layer;

refilling the at least one second inverted trapezoidal trench by depositing a fourth dielectric layer, wherein the part of the fourth dielectric layer filled in the at least one second inverted trapezoidal trench forms at least one wedge;

etching part of the fourth dielectric layer and the hardmask to expose part of the second dielectric layer;

applying pressure on the fourth dielectric layer and annealing at temperature about 200 C-800 C to push the at least one wedge toward the at least one pMOSFET, wherein the at least one wedge is pressed by the first dielectric layer or the first dielectric layer is pushed outwards relative to the at least one wedge, which produces a compressive stress in a longitudinal direction (i.e., in the direction of on-current flow) in the channel of the at least one pMOSFET.

According to a third aspect of the invention, there is provided a method of making strained MOSFETs, comprising the steps of:

forming at least one pMOSFET on a semiconductor wafer;

forming a first dielectric layer on the at least one pMOSFET;

forming a second dielectric layer on the top of the first dielectric layer, wherein the second dielectric layer has small viscosity at temperature greater than about 200 C-800 C;

conducting chemical mechanical polishing (CMP) to planarize the second dielectric layer;

forming a hardmask on the top of the second dielectric layer, wherein the hardmask has at least one first opening hole above the area in or near source/drain of the at least one pMOSFET and at least one second opening hole above the gate of the at least one pMOSFET;

forming at least one first inverted trapezoidal trench in or near source/drain area of the at least one pMOSFET and at least one second inverted trapezoidal trench on the top of the gate of the at least one pMOSFET, wherein both the at least one inverted trapezoidal trench and the at least one second inverted trapezoidal trench extend through the second dielectric layer and the first dielectric layer;

refilling both the at least one inverted trapezoidal trench and the at least one second inverted trapezoidal trench by depositing a third dielectric layer, wherein the third dielectric layer has small viscosity at temperature greater than about 200 C-800 C;

covering the at least one second inverted trapezoidal trench with photo resist;

forming at least one third inverted trapezoidal trench above the area in or near source/drain of the at least one pMOSFET while the at least one second inverted trapezoidal trench is filled by the third dielectric layer, wherein the bottom of the at least one third inverted trapezoidal trench is preferably close or near the top surface of the first dielectric layer and the at least one third inverted trapezoidal trench does not extend through the third dielectric layer;

refilling the at least one third inverted trapezoidal trench by depositing a fourth dielectric layer, wherein the part of the fourth dielectric layer filled in the at least one third inverted trapezoidal trench forms at least one wedge;

etching part of the fourth dielectric layer and the hardmask to expose part of the second dielectric layer;

applying pressure on the fourth dielectric layer and annealing at temperature about 200 C-800 C to push the at least one wedge toward the at least one pMOSFET, wherein the at least one wedge is pressed by the first dielectric layer or the first dielectric layer is pushed outwards relative to the at least one wedge, which produces a compressive stress in a longitudinal direction (i.e., in the direction of on-current flow) in the channel of the at least one pMOSFET.

According to a fourth aspect of the invention, there is provided a method of making strained complementary MOSFETs (CMOSFETs), comprising the steps of:

forming at least one nMOSFET and at least one pMOSFET on a semiconductor wafer;

forming a first dielectric layer on the at least one nMOSFET and the at least one pMOSFET;

forming a second dielectric layer on the top of the first dielectric layer, wherein the second dielectric layer has small viscosity at temperature greater than about 200 C-800 C;

conducting chemical mechanical polishing (CMP) to planarize the second dielectric layer;

forming a hardmask on the top of the second dielectric layer, wherein the hardmask has at least one first opening hole above at least one opening hole above the gate of the at least one nMOSFET, at least one second opening hole above the area in or near source/drain of the at least one pMOSFET and at least one third opening hole above the gate of the at least one pMOSFET;

forming at least one first inverted trapezoidal trench on the top of the at least one nMOSFET, at least one second inverted trapezoidal trench in or near source/drain area of the at least one pMOSFET and at least one third inverted trapezoidal trench on the top of the gate of the at least one pMOSFET, wherein the at least one inverted trapezoidal trench, the at least one second inverted trapezoidal trench and the at least one third inverted trapezoidal trench extend through the second dielectric layer and the first dielectric layer;

refilling the at least one inverted trapezoidal trench, the at least one second inverted trapezoidal trench and the at least one third inverted trapezoidal trench by depositing a third dielectric layer, wherein the third dielectric layer has small viscosity at temperature greater than about 200 C-800 C;

covering the top surface of filled the at least one second inverted trapezoidal trench and the at least one third inverted trapezoidal trench with a first photo-resist;

forming at least one fourth inverted trapezoidal trench with the hardmask above the gate of the at least one nMOSFET, wherein the bottom of the at least one fourth inverted trapezoidal trench is preferably close or near the top surface of the first dielectric layer and the at least one fourth inverted trapezoidal trench does not extend through the third dielectric layer;

removing the first photo-resist;

covering the top surface of filled the at least one third inverted trapezoidal trench and the at least one fourth inverted trapezoidal trench with a second photo-resist;

forming at least one fifth inverted trapezoidal trench above the area in or near source/drain of the at least one pMOSFET while the at least one third inverted trapezoidal trench is filled by the third dielectric layer, wherein the bottom of the at least one fifth inverted trapezoidal trench is preferably close or near the top surface of the first dielectric layer and the at least one fifth inverted trapezoidal trench does not extend through the third dielectric layer;

removing the second photo-resist;

refilling the at least one third inverted trapezoidal trench by depositing a fourth dielectric layer, wherein the part of the fourth dielectric layer filled in the at least one fourth inverted trapezoidal trench and the at least one fifth inverted trapezoidal trench forms at least one first wedge and at least one second wedge;

etching part of the fourth dielectric layer and the hardmask to expose part of the second dielectric layer;

applying pressure on the fourth dielectric layer and annealing at temperature about 200 C-800 C to push the at least one first wedge toward the at least one nMOSFET and the at least one second wedge toward the at least one pMOSFET, wherein the at least one first wedge and the at least one second wedge are pressed by the first dielectric layer or the first dielectric layer on the at least one nMOSFET is pushed outwards relative to the gate of the at least one nMOSFET and the first dielectric layer on the at least one pMOSFET is pushed outwards relative to the gate of the at least one pMOSFET, which produce a tensile stress in a longitudinal direction (i.e., in the direction of on-current flow) in the channel of the at least one nMOSFET and a compressive stress in a longitudinal direction (i.e., in the direction of on-current flow) in the channel of the at least one pMOSFET.

According to a fifth aspect of the invention, there is provided a strained MOSFET structure comprising:

a MOSFET covered by at least one stressed liner and at least one stressed wedge, wherein the at least one stressed liner has a first stress and the at least one stressed wedge has a second stress.

According to a sixth aspect of the invention, there is provided a strained MOSFET structure comprising:

a MOSFET covered by at least one stressed liner and at least one stressed wedge, wherein the at least one stressed liner and the at least one stressed wedge have compressive stress.

According to a seventh aspect of the invention, there is provided a strained nMOSFET structure comprising:

an nMOSFET covered by at least one stressed wedge and at least one stressed liner, wherein the at least one stressed wedge has compressive stress and is embedded in the at least one stressed liner and on the top of the nMOSFET.

According to an eighth aspect of the invention, there is provided a strained pMOSFET structure comprising:

a pMOSFET covered by at least one stressed wedge and at least one stressed liner, wherein the at least one stressed wedge has compressive stress, the at least one stressed wedge is embedded in the at least one stressed liner, and the at least one stressed wedge is located on the sides of the gate of the pMOSFET.

According to a ninth aspect of the invention, there is provided a strained CMOSFET structure comprising:

at least one nMOSFET and at least one pMOSFET covered by at least one first stressed wedge, at least one second stressed wedge, and at least one stressed liner, wherein the at least one first stressed wedge has compressive stress, the at least one first stressed wedge is embedded in the at least one stressed liner, the at least one first stressed wedge is on the top of the nMOSFET, the at least one second stressed wedge has compressive stress, the at least one second stressed wedge is embedded in the at least one stressed liner, and the at least one second stressed wedge is located on the sides of the gate of the pMOSFET.

### BRIEF DESCRIPTION OF THE DRAWINGS

The features of the invention are believed to be novel and the element characteristics of the invention are set forth with particularity in the appended claims.

The figures are for illustration purposes only and are not drawn to scale. The invention itself, however, both as to organization and method of operation, will best be understood by reference to the following detailed description taken in conjunction with the accompanying drawings in which:

FIGS. 1 to 12 are top or cross sectional views which illustrate the various process steps in forming high performance MOSFETs according to the present invention. FIGS. 12A, 12B, and 11C are the top and cross sectional views illustrating the final structure achieved according to the present invention.

### DETAILED DESCRIPTION OF THE INVENTION

When semiconductor devices (i.e., nMOSFETs and pMOSFETs) are integrated to form a high performance integrated circuit (IC), it is usually need to use different types of strong stresses to enhance the device performance. However, it is difficult to obtain high stresses since the minimum feature size of CMOS devices is too small (less than 200 nm) and the intrinsic stress level in a stressor reaches its maximum limitation. There exists a need for improving IC performance by overcoming the limitations of CMOS scaling and the maximum intrinsic stress level in a stressor.

The present invention addresses the needs described above by providing efficient and low cost structures and methods to improve MOSFET performance with extrinsic strain engineering or stress engineering. The present invention discloses methods to form wedges within proximity of MOSFETs. External forces are applied to move the wedges to produce stress in the channel of the MOSFETs, which enhances the performance of the MOSFETs.

Unlike conventional strain engineering methods disclosed in prior art, the present invention relates to create stressed wedges by moving the stressed wedges relatively in a material with external forces or stresses in an IC manufacturing process. Since the stress level in a stressed wedge is mainly determined by the shape of the stressed wedge and the relative moving distance, it is relatively easier, comparing with the methods of deposition and epi growth of stressed film, to increase stress level by changing the shape and/or the relative moving distance of stressed wedges. Moreover, the stresses produced by the stressed wedges can be easily memorized and used to enhance the performance of MOSFETs.

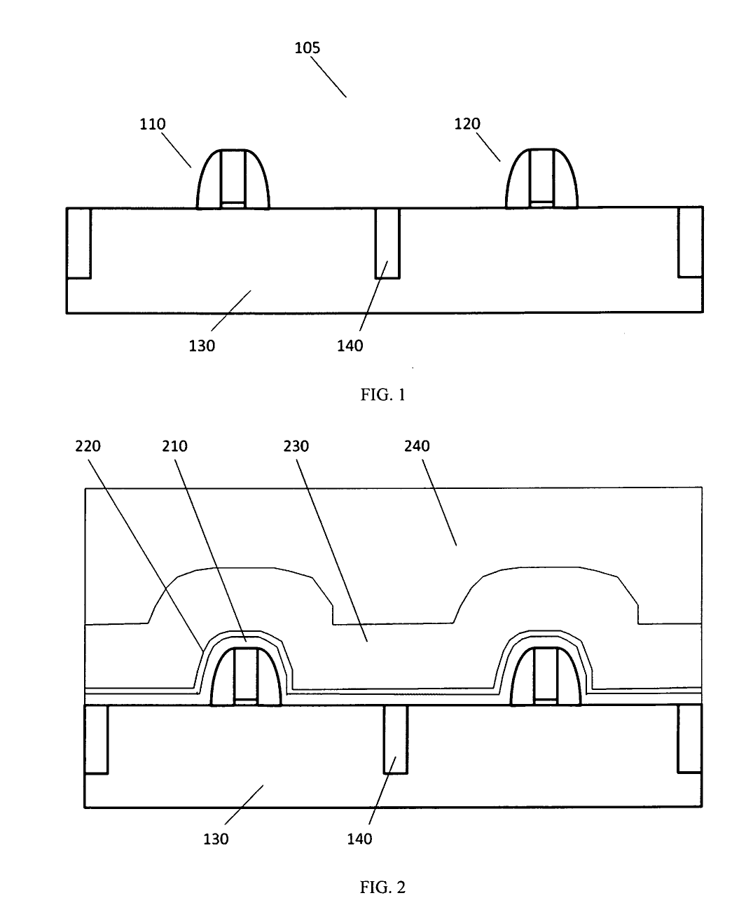

Referring now to the drawings in more detail, FIG. 1 shows a cross-section of a semiconductor structure 105 including at least one nMOSFET 110 and at least one pMOSFET 120, the at least one nMOSFET 110 and the at least one pMOSFET 120 are separated by STI oxide 140 on a semiconductor substrate 130. The semiconductor substrate 130 useful for the present invention is any semiconductor material including but not limited to group IV semiconductors such as silicon, silicon germanium, or germanium, a III-V compound semiconductor, or a II-VI compound semiconductor and combination thereof.

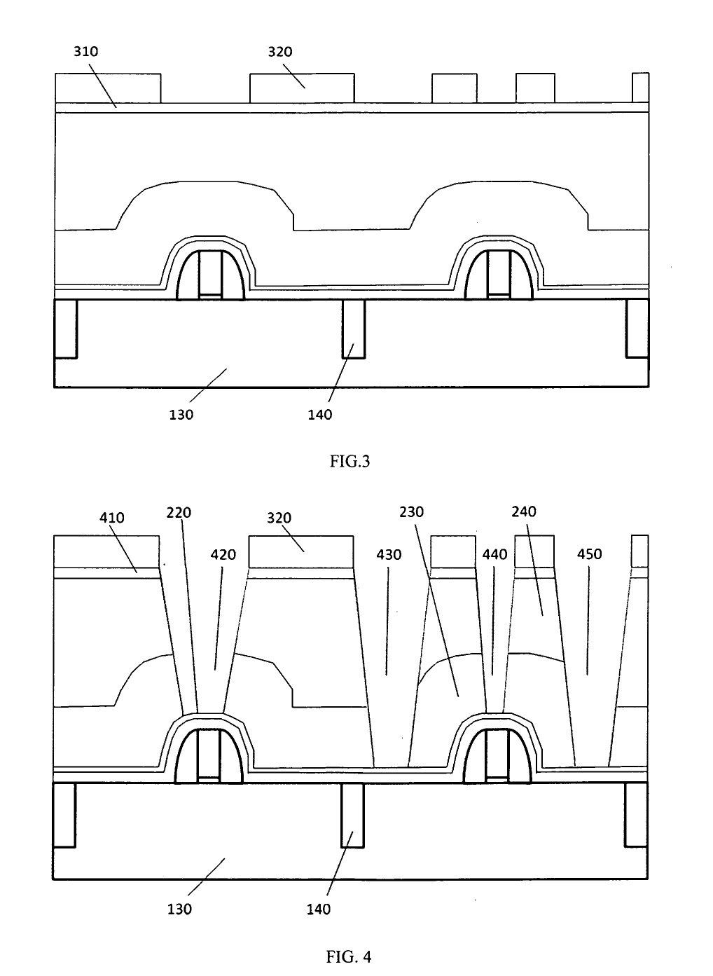

Referring now to FIG. 2, a thin nitride 210 (thickness about 5-20 nm) is deposited on the semiconductor structure 105, a thin oxide 220 (thickness about 2-5 nm) is deposited on the thin nitride 210, another nitride 230 (thickness about 50-150 nm) is deposited on the thin oxide 220, a dielectric material 240 is deposited (if necessary, conducting a chemical mechanical polishing after the deposition to planarize its top surface) on the nitride 230. The thin nitride 210, the thin oxide 220, and the nitride 230 are deposited by any method including but not limited to CVD, PECVD, LPCVD, and ALD. The dielectric material 240 is deposited by any method including but not limited to spin-on, CVD, LPCVD, PECVD, and ALD. The dielectric material 240 useful for the present invention is any insulative material including but not limited to BSG (thickness about 100-300 nm) or BPSG (thickness about 100-300 nm) or adhesive (benzocyclobutene (BCB) or polyimide, thickness about 100-300 nm) and combinations thereof.

Referring now to FIG. 3, a thin amorphous Si 310 (thickness about 10-20 nm) is deposited on the dielectric material 240 and photo resist 320 is patterned with conventional lithographical methods, wherein the photo resist 320 defines hardmask openings.

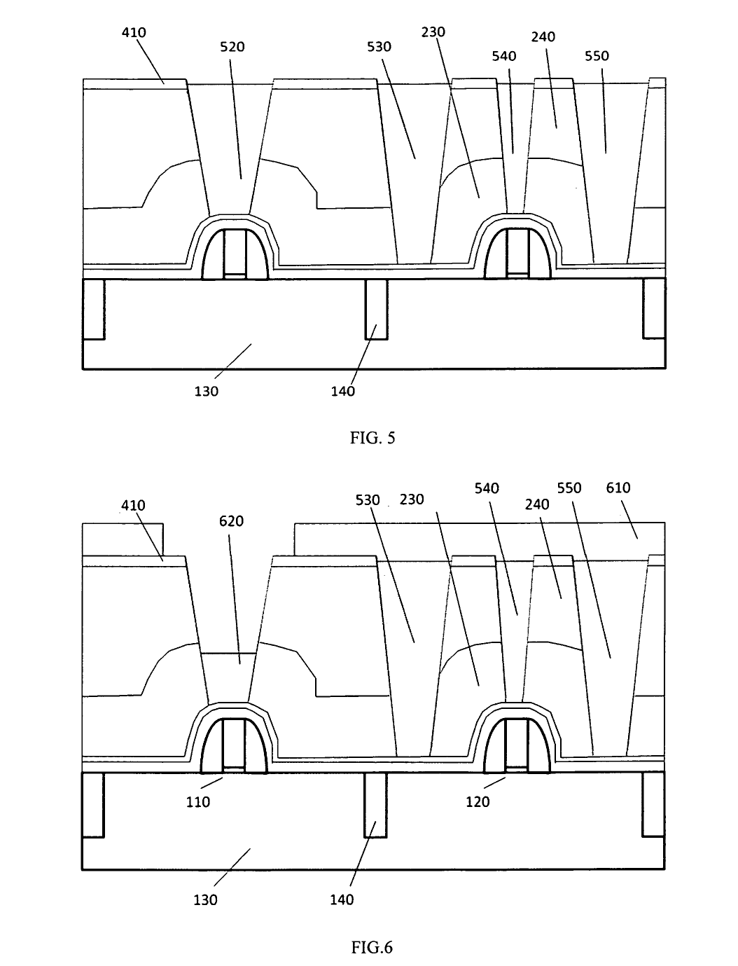

Referring now to FIG. 4, the a-Si 310 is etched to form hardmask 410, the dielectric material 240 is etched stopping on the nitride 230, and the nitride 230 is etched stopping on the thin oxide 220 to form trapezoidal trenches of 420, 430, 440, and 450. The etching methods are any conventional methods including but not limited to reactive-ion-etch (RIE) and dry etch.

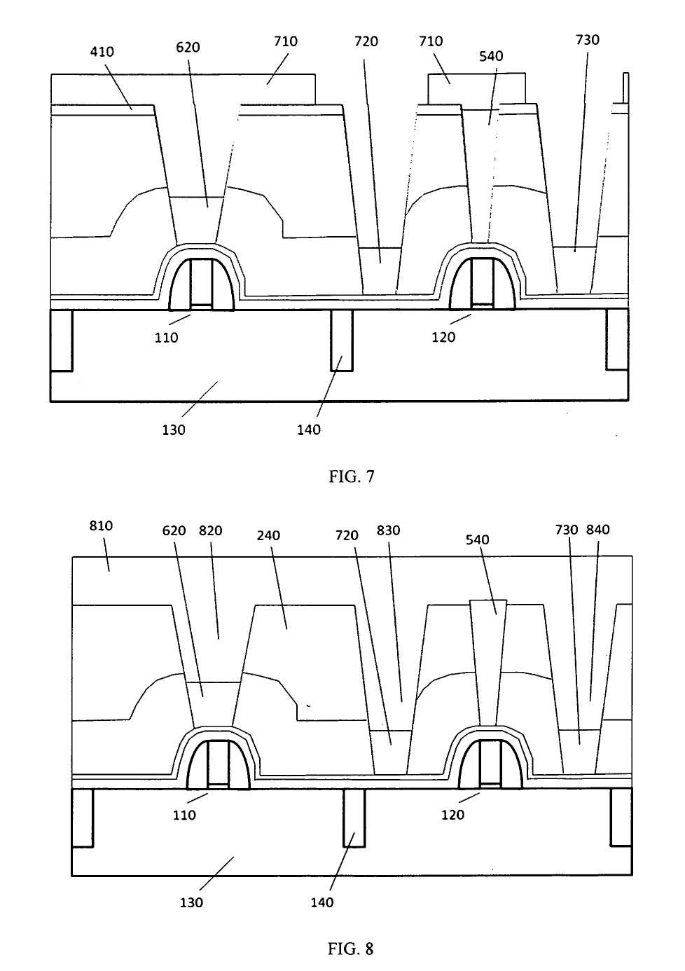

Referring now to FIG. 5, the photo resist 320 is remove with a conventional method of ashing and wet etching, a dielectric material 510 is filled in the trapezoidal trenches of 420, 430, 440, and 450 to form inverted trapezoidal wedges 520, 530, 540, and 550 by a deposition and followed by CMP stopping on the top of a-Si hardmask 410 or etching back to expose the top surface of the hardmask 410. The dielectric material 510 useful for the present invention is any insulative material including but not limited to BSG (thickness about 100-300 nm) or BPSG (thickness about 100-300 nm) or adhesive (benzocyclobutene (BCB) or polyimide, thickness about 100-300 nm) and combinations thereof. Preferably, glass transition temperature of the dielectric material 510 is lower than the dielectric material 240 to avoid possible movement of the hardmask 410. Referring now to FIG. 6, a photo resist 610 is patterned to cover the inverted trapezoidal wedges 530, 540, and 550, and the inverted trapezoidal wedge 520 is etched partially to form an inverted trapezoidal wedge 620. Similarly, as shown in FIG. 7, the photo resist 610 is removed by a conventional method, a photo resist 710 is patterned to cover the inverted trapezoidal wedges 540 and 620, and the inverted trapezoidal wedges 530 and 540 are etched partially to form trapezoidal wedges 720 and 730.

Referring now to FIG. 8, the photo resist 710 is removed, a-Si hardmask 410 is etch with a conventional method, and a nitride 810 is deposited (thickness about 10-200 nm) to form inverted trapezoidal wedges 820, 830, and 840. The nitride 810 is deposited by any method including but not limited to CVD, PECVD, and ALD.

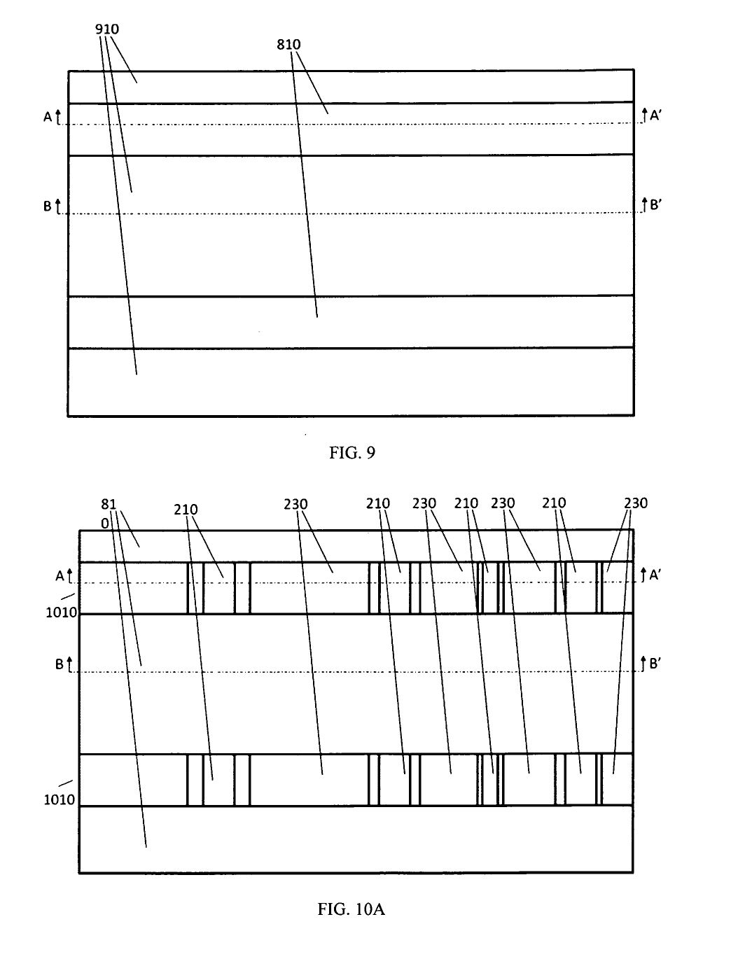

Referring now to a top view of FIG. 9, a photo resist 910 is patterned to partially expose the top surface of the nitride 810. Preferably, the deposition temperature is lower than the glass transition temperatures of the dielectric materials 240 and 510.

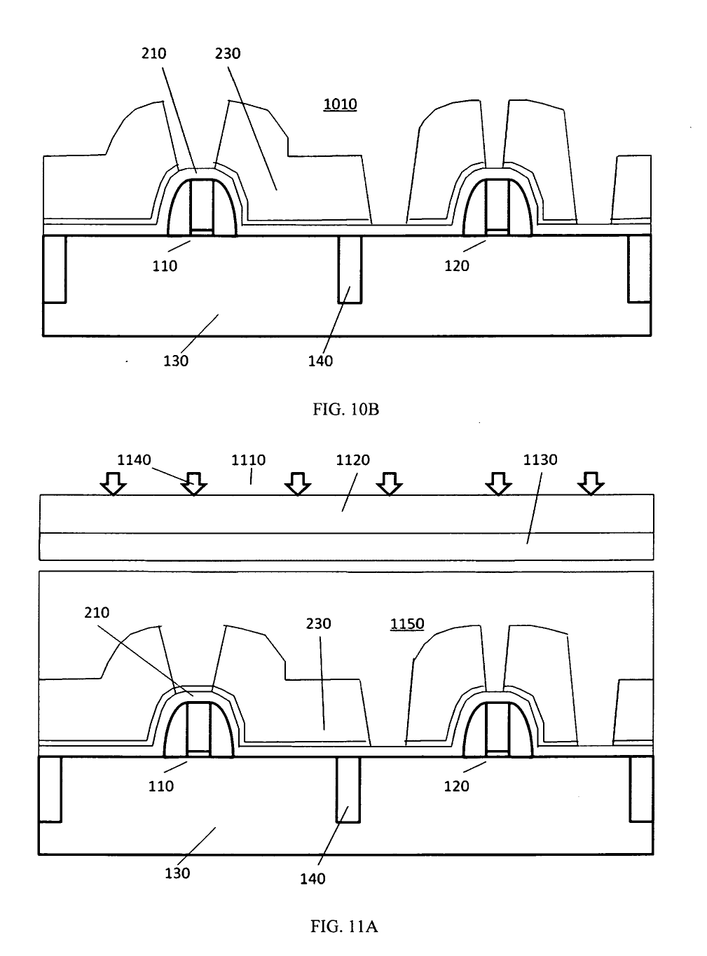

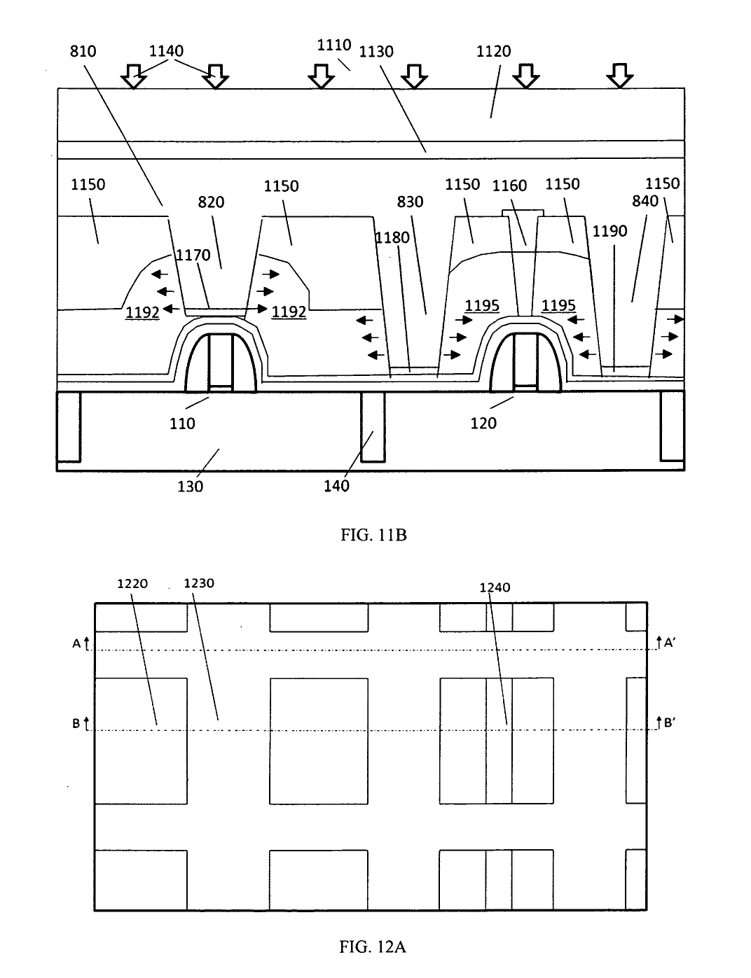

Referring now to FIGS. 10A and 10B, the exposed part of the nitride 810 is etched selective to the dielectric materials 240 and 510, the dielectric materials 240 and 510 are etched selective to the nitrides 210 and 230, the photo resist 910 is removed, and gaps 1010 are formed. In more detail, after the etching, FIG. 10A shows the top view and FIG. 10B shows a cross-section through the gap 1010 or cutting along A-A′ shown in FIG. 10A. The cross-section cutting along B-B′ shown in FIG. 10A is the same as that shown in FIG. 8 since this part is protected by the photo resist 910 and not etched.

Referring now to FIGS. 11A and 11B, a metal wafer 1110 which contains a metal plate 1120 and a graphite layer 1130 on the metal plate 1120 is put on the nitride 810 (preferably, the graphite layer 1130 is faced to the top surface of the nitride 810), a pressure 1140 is applied on the metal wafer 1110 and at the same time the dielectric material 240 and the inverted trapezoidal wedges 540, 620, 720, and 730 are heated up to a temperature around or above the glass transition temperature of the dielectric material 240 and 510 in order to push, as shown in FIG. 11B, the wedge 820 moving toward relatively to the nMOSFET 110 and the wedges 830 and 840 moving toward relatively to the pMOSFET 120. In this process a plastic deformation of the dielectric material 240 and the inverted trapezoidal wedges 540, 620, 720, and 730 takes place while the nitride 230 and the inverted trapezoidal wedges 820, 830, and 840 are rigid. Due to the plastic deformation, the dielectric materials 240 and 510 (the material used to form the inverted trapezoidal wedges 540, 620, 720, and 730) flow into the gaps 1010 to form a dielectric material 1150 which is shown in FIG. 11A and the dielectric material 240 and the inverted trapezoidal wedges 540, 620, 720, and 730 become the dielectric material 1150 and the inverted trapezoidal wedges 1160, 1170, 1180, and 1190, respectively. Dielectrics layers 1192 are pushed outwards relative to the inverted trapezoidal wedge 820, which produces a tensile stress in a longitudinal direction (i.e., in the direction of on-current flow) in the channel of the nMOSFET 110. In contrast, dielectrics layers 1195 are pushed by the inverted trapezoidal wedges 830 and 840 inwards relative to the inverted trapezoidal wedge 1160, which produces a compressive stress in a longitudinal direction (i.e., in the direction of on-current flow) in the channel of the pMOSFET 120. As a result, the performances both of the nMOSFET 110 and the pMOSFET 120 are improved. The pressure 1140 is about 50-500 atmospheres. In one embodiment, the methods for heating up the dielectric material 240, the inverted trapezoidal wedges 540, 620, 720, and 730 includes but not limited to furnace annealing and rapid thermal annealing (RTA) at temperatures about 300 C-900 C In another embodiment, the inverted trapezoidal wedge 1160 can be replaced by a continue liner or cap, for example, a continue nitride cap on the pMOSFET 120 as shown in FIG. 3.

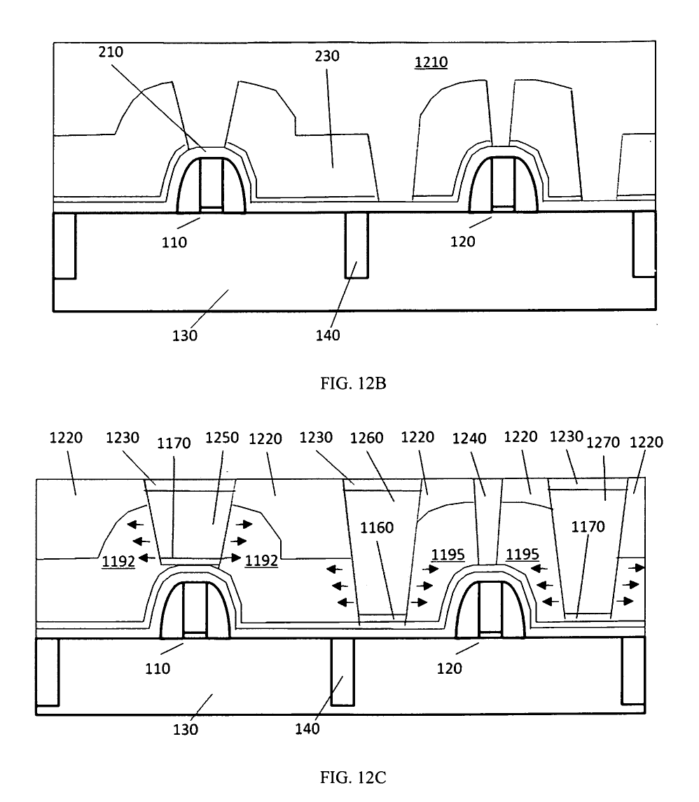

Referring now to FIGS. 12A , 12B and 12C , the dielectric material 1150 and the inverted trapezoidal wedges 1160, 1170, 1180, and 1190 are cooled down with conventional methods, the pressure 1140 is released with conventional methods, the wafer 1110 is removed, the nitride 810 is etched, the inverted trapezoidal wedges 820, 930, and 840 is partially etched to form inverted trapezoidal wedges 1250, 1260, and 1270, an oxide film is deposited and followed by a CMP to form an oxide layer 1230. After the CMP, the dielectric material 1150 and the inverted trapezoidal wedges 1160 become a dielectric material 1220 and an inverted trapezoidal wedge 1240, respectively. In one embodiment, the top surfaces of inverted trapezoidal wedges 1250, 1260, and 1270 are preferably higher than the surfaces of the dielectrics layers 1192 and 1195. After these process steps, the stresses created in the processes shown in FIG. 11 are memorized (as shown FIG. 12C by the arrows) and as a consequence the performances both of the nMOSFET 110 and the pMOSFET 120 are enhanced. After this step, a conventional method can be used to form metal contacts. In one embodiment, metal contacts are preferably formed in the areas shown in the cross-section of FIG. 12B or outside the areas of the inverted trapezoidal wedges 1250, 1260, and 1270.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. semiconductor device comprising:
at least one metal-oxide-semiconductor field effect transistor (MOSFET) including source and drain regions located in a semiconductor substrate, the source and drain regions separated by a channel of the at least one MOSFET, a gate structure located on the channel and in between the source and drain regions, a dielectric layer within said semiconductor substrate located over the source and drain regions and the gate structure, at least one stress-inducing wedge embedded in the dielectric layer, wherein said at least one stress-inducing wedge has one or more sidewall surfaces that are slanted in relation to an upper surface of said semiconductor substrate and applies stress to the channel of said at least one MOSFET.

2. The semiconductor device of claim 1, wherein said dielectric layer is made of at least one of silicon nitride, SiO₂, oxynitride and combinations thereof.

3. The semiconductor device of claim 1, wherein said at least one stress-inducing wedge is made of at least one of silicon nitride, SiO₂, oxynitride , Cu, W, Al, Ni, WN, Ti, TiN, TaN, Ta, TiAl, Au, Cr, CrSi₂, Ge, Mo, MoSi₂, Pd, PdSi₂, Pt, PtSi, TaSi₂, TiSi₂, W, WSi₂, ZrSi₂ and a combination thereof.

4. The semiconductor device of claim 1, wherein said at least one MOSFET is n-channel MOSFET.

5. The semiconductor device of claim 4, wherein said at least one stress-inducing wedge is located above the gate structure of said n-channel MOSFET.

6. The semiconductor device of claim 5, wherein said gate structure has a height about 30 nm-70 nm.

7. The semiconductor device of claim 1, wherein said at least one MOSFET is p-channel MOSFET.

8. The semiconductor device of claim 7, wherein said at least one stress-inducing wedge is located the area where is in or near said source and drain regions, but not above the gate structure of said p-channel MOSFET.

9. The semiconductor device of claim 1, wherein said at least one stress-inducing wedge has compressive stress.

10. The semiconductor device of claim 1, wherein said semiconductor substrate is at least one of semiconductor-on-insulator structure, bulk semiconductor structure, hybrid crystalline orientation semiconductor structure, Si, Ge, SiₓGe₁₋ₓ, InP, GaAs, InAs, GaN, GaP, GaAsN, InGaN, InₓGa₁₋ₓAs, AlₓGa₁₋ₓAs, and a combination thereof.

11. A method, comprising:
(a) providing a semiconductor wafer, wherein the semiconductor wafer contains a semiconductor substrate, an upper surface of said semiconductor substrate, and at least one MOSFET on the upper surface, said at least one MOSFET including source and drain regions located on the upper surface of the semiconductor substrate, the source and drain regions separated by a channel of the at least one MOSFET, a gate structure located on the channel and in between the source and drain regions;
(b) depositing a first dielectric layer on the upper surface of the semiconductor substrate and over the at least one MOSFET;
(c) forming a second dielectric layer over the first dielectric layer, wherein said second dielectric layer has glass transition temperature about 200 C-800 C;
(d) forming a hardmask on the second dielectric layer, wherein the hardmask has at least one opening located the area where is in or near the at least one MOSFET;
(e) etching at least one first inverted trapezoidal trench extending through the second dielectric layer and at least partially into the first dielectric layer, wherein the at least one first inverted trapezoidal trench is located the area where is in or near the at least one MOSFET;
(f) refilling the at least one first inverted trapezoidal trench with a third dielectric layer, wherein said third dielectric layer has glass transition temperature about 200 C-800 C and equal to or lower than the glass transition temperature of the second dielectric layer;
(g) recessing the third dielectric layer in the at least one first inverted trapezoidal trench to form at least one second inverted trapezoidal trench, wherein the bottom of the at least one second inverted trapezoidal trench is in the first dielectric layer but not extending through the third dielectric layer;
(h) etching the hardmask;
(i) refilling the at least one second inverted trapezoidal trench with a rigid material to form at least one inverted trapezoidal wedge;
(j) forming free space around the at least one inverted trapezoidal wedge;
(k) annealing the second dielectric layer and the third dielectric layer at a temperature about 200 C-800 C, and at the same time applying an external pressure on the at least one inverted trapezoidal wedge to push the at least one inverted trapezoidal wedge into or further into the first dielectric layer, wherein and the second dielectric layer and the third dielectric layer are deformed plastically and at least partially flow into the free space created in step (i), the first dielectric layer is pressed by the at least one inverted trapezoidal wedge and then applying stresses on the channel of the at least one MOSFET;
(l) cooling down the second dielectric layer and the third dielectric layer; and
(m) releasing the external pressure applied on the at least one inverted trapezoidal wedge.

12. The method of claim 11, wherein said first dielectric layer is made of at least one of silicon nitride, SiO₂, oxynitride and a combination thereof.

13. The method of claim 11, wherein said second dielectric layer is made of at least one of BPSG, BSG, PSG, PIQ Coupler-3 or benzocyclobutene, and a combination thereof.

14. The method of claim 11, wherein said third dielectric layer is made of at least one of BPSG, BSG, PSG, PIQ Coupler-3 or benzocyclobutene, and a combination thereof.

15. The method of claim 11, wherein said at least one inverted trapezoidal wedge is at least one of silicon nitride, Si0₂, oxynitride , Cu, W, Al, Ni, WN, Ti, TiN, TaN, Ta, TiAl, Au, Cr, CrSi₂, Ge, Mo, MoSi₂, Pd, PdSi₂, Pt, PtSi, TaSi₂, TiSi₂, W, WSi₂, ZrSi₂ and a combination thereof.

16. The method of claim 11, wherein said external pressure is about 50-500 atmospheres.

17. The method of claim 11, wherein said at least one MOSFET is n-channel MOSFET.

18. The method of claim 17, wherein said at least one inverted trapezoidal wedge is located above the gate structure of said n-channel MOSFET.

19. The method of claim 11, wherein said at least one MOSFET is p-channel MOSFET.

20. The method of claim 19, wherein said at least one inverted trapezoidal wedge is located the area where is in or near said source and drain regions, but not above the gate structure of said p-channel MOSFET.
